(19) United States
(12) Patent Application Publication
(10) Pub. No.: US 2026/0190800 A1
(43) Pub. Date: Jul. 2, 2026

(54) Display Device

(71) Applicant: LG Display Co., Ltd., Seoul (KR)

(72) Inventors: Youngsub Shin, Goyang-si (KR); DaBin Kim, Changwon-si (KR)

(21) Appl. No.: 19/432,696

(22) Filed: Dec. 24, 2025

(30) Foreign Application Priority Data
Dec. 31, 2024 (KR) 10-2024-0202425

(51) Int. Cl. H10K 59/80; H10K 59/121; H10K 59/123; H10K 59/124; H10K 102/00

(52) U.S. Cl. CPC H10K 59/877; H10K 59/1213; H10K 59/123; H10K 59/124; H10K 59/879; H10K 59/8792; H10K 2102/331

(57) ABSTRACT

A display device presented herein includes a substrate including a display area in which a plurality of sub pixels are disposed, a thin film transistor disposed on the substrate and including an active layer, a gate electrode, and a first source-drain electrode pattern, a planarization layer disposed on the thin film transistor, a light emitting element disposed on the planarization layer to correspond to each of the plurality of sub pixels, an encapsulation layer disposed on the light emitting element, a plurality of optical control layers disposed on the encapsulation layer to correspond to each of the plurality of sub pixels, a plurality of color filters disposed on the optical control layer to partition the plurality of color filters from each other. The optical control layer includes a light scattering layer disposed on the encapsulation layer and a light concentrating layer disposed on the light scattering layer.

### CROSS-REFERENCE TO RELATED APPLICATION

The present application claims priority to Republic of Korea Patent Application No. 10-2024-0202425 filed on Dec. 31, 2024, which is incorporated herein by reference in its entirety.

### BACKGROUND

### Field

The present disclosure relates to a display device, and more particularly, to a display device in which reflectance is lowered while maintaining a high transmittance and distortion due to external light is improved.

### Discussion of Related Art

In general, an organic light emitting display device includes an anode, a cathode, and an organic emission layer disposed therebetween. As the cathode is formed using a metal material having a high reflectance, external light is reflected by the metal material to degrade visibility and a contrast ratio. Accordingly, in order to reduce reflection due to external light, a polarizing plate for absorbing external light is disposed under the cover member. The polarizing plate is a film having a predetermined level of light transmittance and absorbs external light and reflected light thereof to improve display quality.

Recently, as interest in flexible and slim display devices has increased, a display device to which a relatively thin coated polarizing film is applied instead of a thick polarizing plate has been proposed. However, the coated polarizing film also has a problem in that the thickness is thick, and when the thickness is reduced, the function and display quality of the polarizing film are deteriorated.

Therefore, a Color Filter on Encapsulation (CoE) structure was proposed instead of a polarizing plate or a coated polarizing film. The conventional CoE structure is a structure in which a black matrix and a color filter are disposed on an encapsulation layer. Such a CoE structure has an advantage in that the thickness is thinner than that of the polarizing plate, and the reflectance may be lowered while maintaining high luminance.

### SUMMARY

The conventional CoE structure transmits light emitted from the light emitting element well, but has a disadvantage in that the reflectance is slightly higher than that of the polarizing plate. In addition, since the CoE structure cannot polarize light, there is a problem in that light introduced from the outside is distorted inside the panel. Specifically, there is a problem in that light of different colors is reflected in the horizontal direction by external light or rainbow mura is generated to degrade display quality.

Accordingly, an object to be achieved by the present disclosure is to provide a display device in which reflectance is lowered while maintaining a high transmittance and distortion due to external light is improved.

Objects of the present disclosure are not limited to the above-mentioned objects, and other objects, which are not mentioned above, can be clearly understood by those skilled in the art from the following descriptions.

According to one or more embodiments of the present disclosure, a display device includes a substrate including a display area in which a plurality of sub pixels is disposed, a thin film transistor disposed on the substrate and including an active layer, a gate electrode, and a first source-drain electrode pattern, a planarization layer disposed on the thin film transistor, a light emitting element disposed on the planarization layer so as to correspond to each of the plurality of sub pixels, an encapsulation layer disposed on the light emitting element, a plurality of optical control layers disposed on the encapsulation layer so as to correspond to each of the plurality of sub pixels, a plurality of color filters disposed on the optical control layer so as to partition the plurality of color filters from each other, and the optical control layer includes a light scattering layer disposed on the encapsulation layer and a light concentrating layer disposed on the light scattering layer.

Other detailed matters of the embodiments are included in the detailed description and the drawings.

The display device according to one or more embodiments of the present disclosure has a low reflectance while maintaining a high transmittance of light emitted from the organic light emitting element, and is improved in distortion of external light such as rainbow mura, thereby securing excellent display quality.

The effects according to the present disclosure are not limited to the contents exemplified above, and more various effects are included in the present disclosure.

### BRIEF DESCRIPTION OF DRAWINGS

The above and other embodiments, features and other advantages of the present disclosure will be more clearly understood from the following detailed description taken in conjunction with the accompanying drawings, in which:

FIG. 1 is a system configuration diagram of a display device according to one or more embodiments of the present disclosure.

FIG. 2 is a cross-sectional view of a display area of a display panel according to one or more embodiments of the present disclosure.

FIG. 3 is a plan view illustrating a placement structure of a plurality of sub pixels in a display area of a display panel according to one or more embodiments of the present disclosure.

FIG. 4A is an image showing a left-right (X-axis direction) cross-section of a red sub pixel according to one or more embodiments of the present disclosure.

FIG. 4B is an image showing an up-down (Y-axis direction) cross-section of a red sub pixel according to one or more embodiments of the present disclosure.

FIG. 5A is an image showing a left-right (X-axis direction) cross-section of a green sub pixel according to one or more embodiments of the present disclosure.

FIG. 5B is an image showing an up-down (Y-axis direction) cross-section of a green sub pixel according to one or more embodiments of the present disclosure.

FIG. 6 is a schematic diagram for explaining that a non-flat anode influences reflection of light according to one or more embodiments of the present disclosure.

FIG. 7 is a schematic cross-sectional view of a display device including an optical control layer according to one or more embodiments of the present disclosure.

FIG. 8 is a view of an optical control layer according to one or more other embodiments of the present disclosure.

FIG. 9 is a plan view illustrating a placement structure of a plurality of sub pixels in a display area of a display panel according to one or more other embodiments of the present disclosure.

FIG. 10 is a schematic cross-sectional view of a display device according to one or more other embodiments of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. The terms such as “including,” “having,” “comprising,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, embodiments of the present disclosure will be described in detail with reference to accompanying drawings.

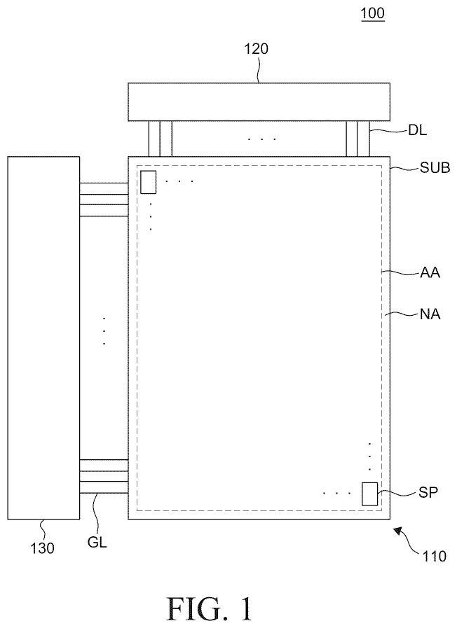

FIGS. 1 to 3 are diagrams for explaining a basic structure of a display device according to one or more embodiments of the present disclosure.

First, FIG. 1 is a system configuration diagram of a display device according to one or more embodiments of the present disclosure. Referring to FIG. 1, a display device 100 may include a display panel 110 and a display driving circuit.

The display driving circuit is a circuit for driving the display panel 110. The display driving circuit may include a data driving circuit 120 and a gate driving circuit 130. The data driving circuit 120 is a circuit configured to drive a plurality of data lines DL and may output data signals to the plurality of data lines DL. The gate driving circuit 130 is a circuit configured to drive a plurality of gate lines GL and may output gate signals to the plurality of gate lines GL.

The display panel 110 may be an organic light emitting display panel including an organic light emitting element, but is not limited thereto.

The display panel 110 may include a display area AA in which an image is displayed and a non-display area NA in which an image is not displayed.

The display area AA is an area in which images are displayed on the display panel 110. In the display area AA, a plurality of sub pixels SP constituting a plurality of pixels and a circuit for driving the plurality of sub pixels SP may be disposed. The plurality of sub pixels SP is a minimum unit constituting the display area AA, and a display element may be disposed in each of the plurality of sub pixels SP, and the plurality of sub pixels SP may constitute a pixel. For example, an organic light emitting element including an anode, an emission layer, and a cathode may be disposed in each of the plurality of sub pixels SP, but it is not limited thereto. Further, a circuit for driving the plurality of sub pixels SP may include components such as a driving element and a wiring line. For example, the circuit may include a thin film transistor, a storage capacitor, a gate line, a data line, and the like, but is not limited thereto.

The non-display area NA is an area where an image is not displayed. The non-display area NA may be an outer peripheral area of the display area AA, and may be referred to as a bezel area. The entire or part of the non-display area NA may be an area visible from the front surface of the display device 100, or an area that is bent and not visible from the front surface of the display device 100.

In the non-display area NA, various wiring lines and circuits for driving light emitting elements disposed in the display area AA may be disposed. For example, in the non-display area NA, link lines for transmitting signals to the plurality of sub pixels SP and circuits of the display area AA, gate in panel (GIP) lines, or driving ICs such as gate driver ICs and data driver ICs may be disposed, but it is not limited thereto.

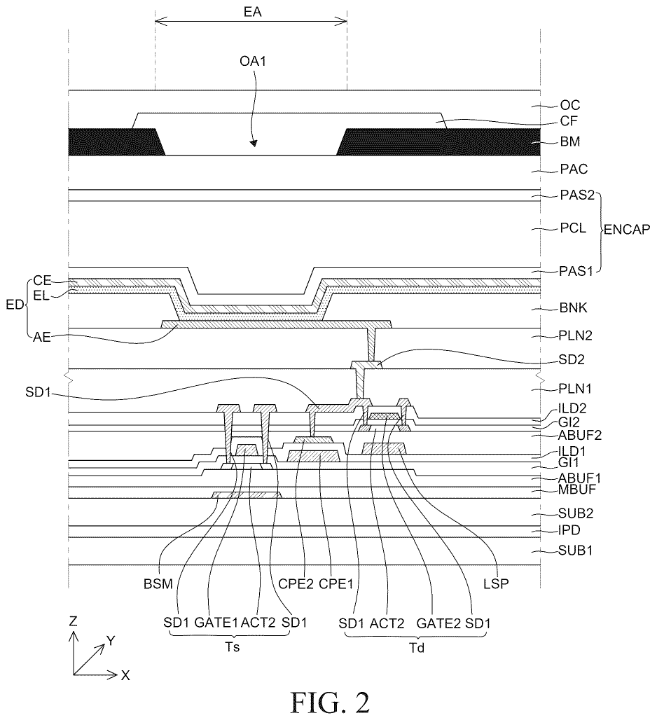

FIG. 2 is a cross-sectional view of a display area of a display panel according to one or more embodiments of the present disclosure.

The display panel 110 may include a substrate SUB, a plurality of thin film transistors Td and Ts, a planarization layer PLN, a light emitting element ED, an encapsulation layer ENCAP, a black matrix BM, and a color filter CF.

The substrate SUB may include a first substrate SUB1, an interlayer insulating film IPD, and a second substrate SUB2. The interlayer insulating film IPD may be positioned between the first substrate SUB1 and the second substrate SUB2. As described above, the interlayer insulating film IPD is configured between the first substrate SUB1 and the second substrate SUB2 to suppress the permeation of moisture. For example, the first substrate SUB1 and the second substrate SUB2 may be polyimide (PI) substrates.

Various elements constituting the display panel 110 may be disposed on the substrate SUB. The lower protection metal layer BSM and the multi-buffer layer MBUF are disposed on the second substrate SUB2. The lower protection metal layer BSM may be a light blocking layer that blocks light. The lower protection metal layer BSM may prevent the characteristics of the thin film transistor from being changed by light introduced during the process.

The multi-buffer layer MBUF may be disposed on the lower protection metal layer BSM. The multi-buffer layer MBUF may prevent penetration of moisture or the like and block various foreign substances or defects that may be introduced during the process.

The first active buffer layer ABUF1 may be disposed on the multi-buffer layer MBUF, and the first active layer ACT1 of the switching thin film transistor Ts may be disposed on the first active buffer layer ABUF1.

The first active layer ACT1 may be formed of polycrystalline silicon, amorphous silicon, or oxide semiconductor, but is not limited thereto.

A first gate insulating film GI1 is disposed on the first active layer ACT1.

The first gate electrode GATE1 of the switching thin film transistor Ts and the first metal layer CPE1 are disposed on the first gate insulating film GI1. For convenience of processing, each of the first gate electrode GATE1 and the first metal layer CPE1 may be formed of the same material in the same process.

The first gate electrode GATE1 may be disposed to overlap the channel region of the first active layer ACT1 with the first gate insulating film GI1 interposed therebetween.

A first interlayer insulating film ILD1 is disposed on the first gate electrode GATE1 and the first metal layer CPE1.

The second metal layer CPE2 and the light blocking pattern LSP are disposed on the first interlayer insulating film ILD1. A capacitor may be implemented by disposing the second metal layer CPE2 so as to overlap the first metal layer CPE1 with the first interlayer insulating film ILD1 interposed therebetween. The second metal layer CPE2 may be electrically connected to the first source-drain electrode pattern SD1, which may be the second source electrode or the second drain electrode of the driving transistor Td. However, the present disclosure is not limited thereto. The connection relationship may vary depending on the design of the pixel driving circuit.

The light blocking pattern LSP may be disposed to overlap the second active layer ACT2 of the driving thin film transistor Td to be described later. Accordingly, the light blocking pattern LSP may prevent the characteristics of the thin film transistor from being changed by light introduced during the process.

The second metal layer CPE2 and the light blocking pattern LSP may be formed of the same material in the same process for convenience.

The second active buffer layer ABUF2 may be disposed on the second metal layer CPE2 and the light blocking pattern LSP. The second active buffer layer ABUF2 may planarize a surface on which the driving thin film transistor Td is to be formed.

The second active layer ACT2 of the driving thin film transistor Td is disposed on the second active buffer layer ABUF2. The second active layer ACT2 may be formed of polycrystalline silicon, amorphous silicon, or oxide semiconductor, but is not limited thereto. The second active layer ACT2 may be disposed to overlap the light blocking pattern LSP with the second active buffer layer ABUF2 interposed therebetween.

The second gate insulating film GI2 is disposed on the second active layer ACT2, and the second gate electrode GATE2 is disposed on the second gate insulating film GI2. The second gate electrode GATE2 may be disposed to overlap the channel region of the second active layer ACT2 with the second gate insulating film GI2 interposed therebetween.

A second interlayer insulating film ILD2 may be disposed on the second gate electrode GATE2.

At least four first source-drain electrode patterns SD1 may be disposed on the second interlayer insulating film ILD2. One of the first source-drain electrode pattern SD1 may be a first source electrode of the switching transistor Ts, the other may be a first drain electrode of the switching transistor Ts, the other may be a second source electrode of the driving transistor Td, and the other may be a second drain electrode of the driving transistor Td.

Two of the four first source-drain electrode patterns SD1 may be connected to one side and the other side of the first active layer ACT1 through contact holes formed in the second interlayer insulating film ILD2, the second gate insulating film GI2, the second active buffer layer ABUF2, the first interlayer insulating film ILD1, and the first gate insulating film GI1, respectively. Accordingly, the first active layer ACT1, the first gate electrode GATE1, and the two first source-drain electrode patterns SD1 implement a switching thin film transistor Ts. When the first active layer ACT1 is formed of an oxide semiconductor, one side and the other side of the first active layer ACT1 connected to the first source-drain electrode pattern SD1 may be doped with impurities to become conductive.

The other two of the four first source-drain electrode patterns SD1 may be connected to one side and the other side of the second active layer ACT2 through contact holes formed in the second interlayer insulating film ILD2 and the second gate insulating film GI2, respectively. Accordingly, the second active layer ACT2, the second gate electrode GATE2, and the two first source-drain electrode patterns SD1 implement the driving thin film transistor Td. When the second active layer ACT2 is formed of an oxide semiconductor, one side and the other side of the second active layer ACT2 connected to the two first source-drain electrode patterns SD1 may be doped with impurities to become conductive.

In addition to the above-described four first source-drain electrode patterns SD1, a first source-drain electrode pattern SD1 may be further disposed on the second interlayer insulating film ILD2. The first source-drain electrode pattern SD1 may be electrically connected to the second metal layer CPE2 through contact holes formed in the second interlayer insulating film ILD2, the second gate insulating film GI2, and the second active buffer layer ABUF2. In addition, the first source-drain electrode pattern SD1, which is electrically connected to the second metal layer CPE2, may be electrically connected to one of the two first source-drain electrode patterns SD1 constituting the driving transistor Td. However, the present disclosure is not limited thereto. The connection relationship may vary depending on the design of the pixel driving circuit.

A first planarization layer PLN1 may be disposed on the first source-drain electrode pattern SD1. The first planarization layer PLN1 covers a plurality of first source-drain electrode patterns SD1 to planarize an upper surface. The first planarization layer PLN1 may be formed of an organic insulating material to cover the electrode material layers and provide a flat surface.

The second source-drain electrode pattern SD2 is disposed on the first planarization layer PLN1. The second source-drain electrode pattern SD2 may be electrically connected to the first source-drain electrode pattern SD1, which may be the second source electrode or the second drain electrode of the driving transistor Td, through a contact hole formed in the first planarization layer PLN1.

A second planarization layer PLN2 is disposed on the second source-drain electrode pattern SD2. The second planarization layer PLN2 covers an upper portion of the second source-drain electrode pattern SD2 to form a planar surface. The second planarization layer PLN2 may have a single-layered structure or a multi-layered structure.

The light emitting element ED is disposed on the second planarization layer PLN2. The light emitting element ED may include an anode AE, an emission layer EL, and a cathode CE.

The anode AE is disposed on the second planarization layer PLN2. The anode AE may be electrically connected to the second source-drain electrode pattern SD2 through a contact hole formed in the second planarization layer PLN2.

In the case of a top emission type in which light emitted from the light emitting element ED is emitted to the top of the display device, the anode AE may further include a reflective layer to allow the light to travel upward.

A bank BNK may be disposed on the second planarization layer PLN2. The bank BNK may be disposed to expose at least a portion of the anode AE. The bank BNK is disposed to cover the end of the anode AE so that a portion corresponding to the emission area of the sub pixel SP may be opened.

The bank BNK may be formed of an inorganic insulating material, such as silicon nitride (SiNx) or silicon oxide (SiOx), or an organic insulating material, such as benzocyclobutene-based resin, acrylic-based resin, or imide-based resin, and may be formed as a single layer or multiple layers, but is not limited thereto. The bank BNK may be formed of a black resin or include a dye capable of absorbing light to prevent color mixture between sub pixels.

A spacer may be further disposed on the bank BNK.

The emission layer EL may be disposed on the anode AE. The emission layer EL is not separated for each of the plurality of sub pixels and may be formed as a common layer, but is not limited thereto. The emission layer EL may be disposed on the anode AE so as to correspond to an emission area of each of the plurality of sub pixels. The light emitting element ED may further include a plurality of organic films other than the emission layer EL.

The cathode CE is disposed on the emission layer EL. The cathode CE is not separated for each of the plurality of sub pixels and may be formed as a common layer.

An encapsulation layer ENCAP may be disposed on the light emitting element ED. The encapsulation layer ENCAP may have a single-layer structure or a multi-layer structure. For example, the encapsulation layer ENCAP may include a first encapsulation layer PAS1, a second encapsulation layer PCL, and a third encapsulation layer PAS2. In this case, the first encapsulation layer PAS1 and the third encapsulation layer PAS2 may be inorganic layers, and the second encapsulation layer PCL may be an organic layer. The second encapsulation layer PCL, which is an organic film, may be applied thickly, such that the upper portion of the light emitting element ED may be planarized, impact may be easily absorbed, and foreign matter introduced during the process may be covered.

Although not illustrated in the drawings, a touch sensor may be disposed on the encapsulation layer ENCAP as necessary.

The protective layer PAC is disposed on the encapsulation layer ENCAP, and the black matrix BM and the plurality of color filters CF are disposed on the protective layer PAC.

The protective layer PAC prevents damage to layers disposed under the protective layer PAC during a process of forming the color filter CF and the black matrix BM.

The protective layer PAC may be formed of an inorganic material or an organic material. For example, the protective layer PAC may be formed of an inorganic material such as silicon nitride (SiNx), silicon oxide (SiOx), aluminum oxide (AlOx), or silicon oxy nitride (SiON), but is not limited thereto. As another example, the protective layer PAC may be formed of an organic insulating material such as acrylic resin, polyester resin, epoxy resin, silicone-based resin, or polyimide resin, but is not limited thereto.

Light introduced from the outside may be reflected by components such as an anode AE formed of a metal having high reflectivity. The visibility of an image displayed on the display device 100 may be deteriorated by the reflected light.

The plurality of color filters CF and the black matrix BM may absorb external light while maintaining high luminance of light emitted from the light emitting element ED. Accordingly, the plurality of color filters CF and the black matrix BM may serve as an anti-reflection layer that suppresses the generation of reflected light by external light.

The black matrix BM may be disposed on the protective layer PAC to partition the plurality of color filters CF from each other. Accordingly, the black matrix BM prevents color mixture of light emitted from each of the adjacent sub pixels SP.

The black matrix BM may be disposed at a position corresponding to the bank BNK.

Accordingly, the black matrix BM includes the opening OA1 at a position corresponding to the emission area of the light emitting element ED.

A width of the black matrix BM may be different from a width of the bank BNK. For example, the width of the black matrix BM may be formed to be narrower than the width of the bank BNK. Accordingly, the width of the opening OA1 of the black matrix BM is formed to be wider than the width of the opening of the bank BNK. In this case, a pull-back structure in which the end of the black matrix BM corresponding thereto is pulled back more than the end of the bank BNK is formed to secure a wide viewing angle.

The black matrix BM may include a light absorbing material selected from an inorganic black material, such as carbon black, or an organic black material, such as aniline black, lactam black, and perylene black, to absorb external light, but is not limited thereto. As another example, a black dye may be included, or a red dye, a green dye, and a blue dye may be mixed and used.

Each of the plurality of color filters CF is disposed on the protective layer PAC to correspond to each of the plurality of sub pixels SP. Each of the plurality of color filters CF is disposed in the opening OA1 of the black matrix BM. Each of the plurality of color filters CF corresponds to an emission area of the light emitting element ED. Accordingly, each of the plurality of color filters CF may transmit light emitted from the corresponding light emitting element ED. The plurality of sub pixels SP may include a red sub pixel RSP, a green sub pixel GSP, and a blue sub pixel BSP, and the plurality of color filters CF may include a red color filter corresponding to the red sub pixel RSP, a green color filter corresponding to the green sub pixel GSP, and a blue color filter corresponding to the blue sub pixel BSP.

An overcoating layer OC may be disposed on the plurality of color filters CF and the black matrix BM. The overcoating layer OC covers the plurality of color filters CF and the black matrix BM to planarize the upper surface. The overcoating layer OC may be formed of an organic material having excellent flatness and optically transparent.

Although not illustrated in the drawings, a cover member may be bonded onto the overcoating layer OC.

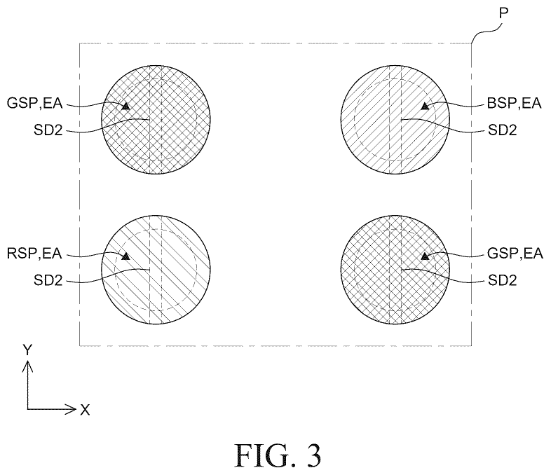

FIG. 3 is a plan view illustrating a placement structure of a plurality of sub pixels in a display area of a display panel according to one or more embodiments of the present disclosure. For convenience of description, in FIG. 3, only the anode AE, the emission layer EL corresponding to the emission area EA, and the second source-drain electrode pattern SD2 are illustrated.

One pixel P may include one blue emission area EA, one red emission area EA, and two green emission areas EA. Sub pixels SP may be disposed in the pixel P.

Accordingly, the red emission area EA and one green emission area EA may be driven as one sub pixel RG sub pixel, and the blue emission area EA and the other green emission area EA may be driven as one sub pixel BG sub pixel. Accordingly, the pixel P is formed by a combination of the RG sub pixel and the BG sub pixel, and the structure of the pixel P may be referred to as an RG-BG pixel structure.

In the present disclosure, the blue light-emitting area may be referred to as a blue sub pixel BSP, the red light-emitting area may be referred to as a red sub pixel RSP, and the green light-emitting area may be referred to as a green sub pixel GSP. That is, the RG sub pixel may be composed of a red sub pixel RSP and a green sub pixel GSP, and the BG sub pixel may be composed of a blue sub pixel BSP and a green sub pixel GSP.

The arrangement and shape of the sub pixels illustrated in FIG. 3 are merely exemplary, but are not limited thereto.

Each of the light-emitting area EA of the red sub pixel RSP, the light-emitting area EA of the green sub pixel GSP, and the light-emitting area EA of the blue sub pixel BSP may be disposed to overlap the second source-drain electrode pattern SD2. Accordingly, the second source-drain electrode pattern SD2 may overlap at least a part of the anode AE formed to correspond to each of the red sub pixel RSP, the green sub pixel GSP, and the blue sub pixel BSP.

For example, the second source-drain electrode pattern SD2 may be a data line which supplies a data voltage supplied from a data driving circuit to each sub pixel to display an image. The data line may be a wiring line extending from a data driving circuit located in one of four areas of the non-display area NA surrounding four sides of the display area AA. For example, the data line extends in the Y-axis direction and may be disposed on the first planarization layer PLN1.

Accordingly, the second source-drain electrode pattern SD2 may be disposed to penetrate each of the emission area EA of the red sub pixel RSP, the emission area EA of the green sub pixel GSP, and the emission area EA of the blue sub pixel BSP in the Y-axis direction. That is, each of the emission area EA of the red sub pixel RSP, the emission area EA of the green sub pixel GSP, and the emission area EA of the blue sub pixel BSP may be located on the second source-drain electrode pattern SD2 extending in the Y-axis direction.

As illustrated in FIG. 2, the second source-drain electrode pattern SD2 may be covered by the second planarization layer PLN2, but the second source-drain electrode pattern SD2 may affect the flatness. Accordingly, a portion of the second planarization layer PLN2 corresponding to a position where the second source-drain electrode pattern SD2 is formed may have a shape that rises more convexly than the surroundings. The shape of the second planarization layer PLN2 may affect the shape of the anode AE formed on the second planarization layer PLN2. Therefore, in the emission area EA of the red sub pixel RSP, the emission area EA of the green sub pixel GSP, and the emission area EA of the blue sub pixel BSP, the anode AE may also have a step corresponding to the second source-drain electrode pattern SD2.

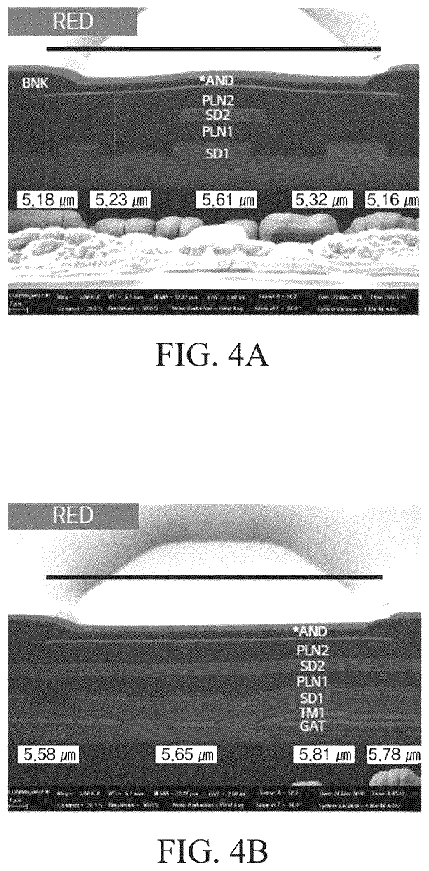

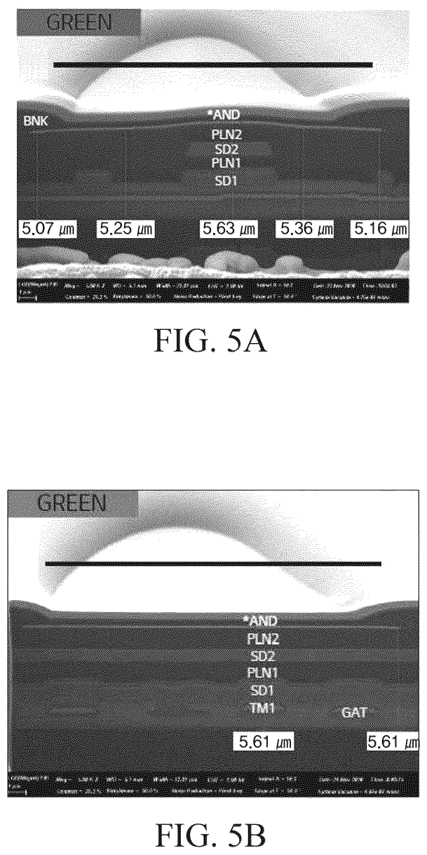

FIGS. 4A, 4B, 5A, and 5B are images showing that a step occurs due to a second source-drain electrode pattern in a sub pixel. FIG. 4A is an image showing a left-right (X-axis direction) cross-section of a red sub pixel, and FIG. 4B is an image showing an up-down (Y-axis direction) cross-section of a red sub pixel. FIG. 5A is an image showing a left-right (X-axis direction) cross-section of a green sub pixel, and FIG. 5B is an image showing an up-down (Y-axis direction) cross-section of a green sub pixel.

Referring to FIG. 4A, as the second source-drain electrode pattern SD2 is formed to extend in the Y-axis direction, it is confirmed that the second planarization layer PLN2 and the anode AE at positions corresponding to the second source-drain electrode pattern SD2 rise convexly in the emission area EA of the red sub pixel RSP on the left-right cross-sectional view. Accordingly, the thickness from the substrate to the edge portion of the anode AE is 5.18 μm, and the thickness to the center portion of the anode AE is 5.61 μm, and the difference between the edge portion and the center portion may be 0.43 μm.

Meanwhile, referring to FIG. 4B, as the second source-drain electrode pattern SD2 is formed to extend in the Y-axis direction, the second source-drain electrode pattern SD2 is formed over the entire emission area EA of the red sub pixel RSP. Accordingly, on the upper-lower cross-sectional view, it can be seen that the difference in thickness between the edge portion (5.58 μm) and the center portion (5.65 μm) is relatively flat at 0.07 μm.

Referring to FIG. 5A, it may be seen that in the case of the green sub pixel GSP, the difference in thickness between the edge portion (5.07 μm) and the center portion (5.63 μm) is 0.56 μm on the left-right cross-sectional view in the same manner as the red sub pixel RSP. In contrast, referring to FIG. 5B, it may be seen that there is no difference in thickness between the edge portion 5.61 μm and the center portion 5.61 μm on the upper-lower cross-sectional view, so that it is relatively flat.

That is, when the second source-drain electrode pattern SD2 is disposed to extend in the Y-axis direction, a step is formed on the anode AE overlapping the second source-drain electrode pattern SD2 in the left-right (X-axis direction) cross-sectional view, which may reduce the flatness.

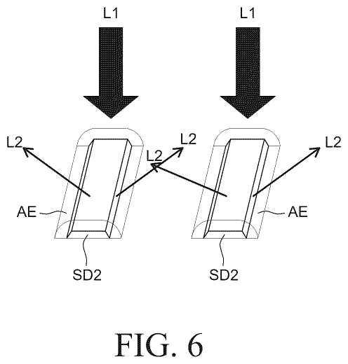

The flatness of the anode AE may affect the reflection of light. FIG. 6 is a schematic diagram for explaining that a non-flat anode influences reflection of light. Referring to FIG. 6, light L1 incident from the outside is reflected by the anode AE having reflectivity to form reflected light. At this time, the center portion of the anode AE is convexly raised in the left-right (X-axis direction) cross-sectional view due to the step difference caused by the second source-drain electrode pattern SD2, so that the amount of light emitted in the horizontal direction may prevail. Such reflected light L2 causes distortion of light due to irregular diffraction and interference in the display panel 110. Accordingly, a phenomenon such as a rainbow mura occurs, which deteriorates the display quality.

In the present disclosure, in order to solve the distortion of light caused by the decrease in the flatness of the anode AE due to the step difference of the second source-drain electrode pattern SD2, a plurality of optical control layers are provided.

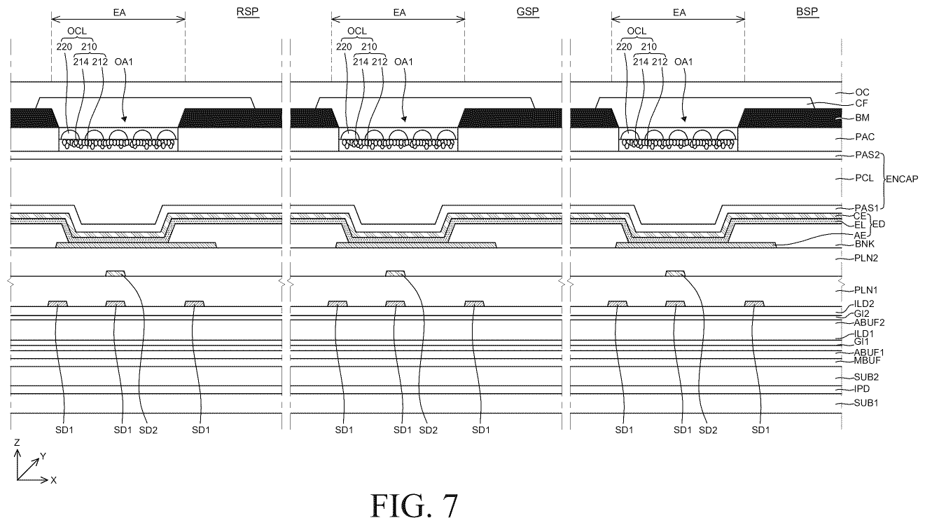

Hereinafter, a display device 100 including an optical control layer will be described with reference to FIG. 7. FIG. 7 is a schematic cross-sectional view of a display device including an optical control layer according to one or more embodiments of the present disclosure. The display device of FIG. 7 is substantially the same as the display device described in FIGS. 1 to 3 except that an optical control layer is further shown. Therefore, redundant descriptions of components having the same reference numerals as those of FIGS. 1 to 3 will be omitted.

Referring to FIG. 7, a display device according to one or more embodiments of the present disclosure includes an optical control layer OCL. The optical control layer OCL may be disposed on the encapsulation layer ENCAP.

The optical control layer OCL may be disposed on the encapsulation layer ENCAP so as to correspond to each of the plurality of sub pixels. The optical control layer OCL may be disposed so as to correspond to the emission area EA of each of the red sub pixel RSP, the green sub pixel GSP, and the blue sub pixel BSP.

For example, the protective layer PAC may include an opening at a position corresponding to the emission area EA of each of the red sub pixel RSP, the green sub pixel GSP, and the blue sub pixel BSP, and the optical control layer OCL may be disposed at the opening of the protective layer PAC.

The optical control layer OCL includes a light scattering layer 210 and a light concentrating layer 220. The light scattering layer 210 is disposed on the encapsulation layer ENCAP, and the light concentrating layer 220 is disposed on the light scattering layer 210.

As described above, the second source-drain electrode pattern SD2 is disposed below the anode AE, which decreases the flatness of the anode AE and increases the amount of reflected light in the X-axis direction. This reflected light caused stains such as rainbow mura.

The light scattering layer 210 scatters reflected light generated by reflecting external light incident into the display panel 110 by a reflective layer such as the anode AE. Accordingly, the light uniformity is improved, and the rainbow mura phenomenon may be weakened.

The light scattering layer 210 may include a base resin 212 and a plurality of light scattering particles 214. For example, the plurality of light scattering particles 214 may be dispersed in the base resin 212. Preferably, the plurality of light scattering particles 214 may be aggregated on the surface of the light scattering layer 210 adjacent to the light concentrating layer 220. That is, the light scattering particles 214 may be aggregated on the upper surface of the light scattering layer 210 and may not be dispersed on the lower surface. In this case, the light scattering particles 214 are aggregated so that cancellation of the interference fringe after the reflected light is scattered may be easier. Accordingly, the light uniformity is further improved, and it may be more advantageous to improve the rainbow mura phenomenon.

The light scattering particles 214 may be at least one selected from TiO₂ particles and SiO₂ particles. These particles have the advantage of excellent light scattering properties. However, the present disclosure is not limited thereto. The light scattering particles 214 may be spherical or hollow particles, but are not limited thereto.

For example, the diameter of the light scattering particles 214 included in the light scattering layer 210 may be 1 nm to 1 μm or 0.1 μm to 1 μm. Within this range, the surface quality of the light scattering layer 210 is excellent, and the light scattering characteristics are excellent. When the diameter of the light scattering particles 214 is too large, haze increases, and optical properties of the display device may deteriorate.

The light concentrating layer 220 is disposed on the light scattering layer 210. If necessary, an adhesive layer may be further disposed between the light concentrating layer 220 and the light scattering layer 210 selectively.

The light concentrating layer 220 condenses light scattered from the light scattering layer 210 to face the outside of the display panel 110, thereby improving light extraction efficiency.

The light concentrating layer 220 may include a plurality of structures. For example, referring to FIG. 7, the light concentrating layer 220 may include a plurality of lenses. Specifically, the light concentrating layer 220 may be composed of a plurality of spherical lenses or a plurality of cylindrical lenses.

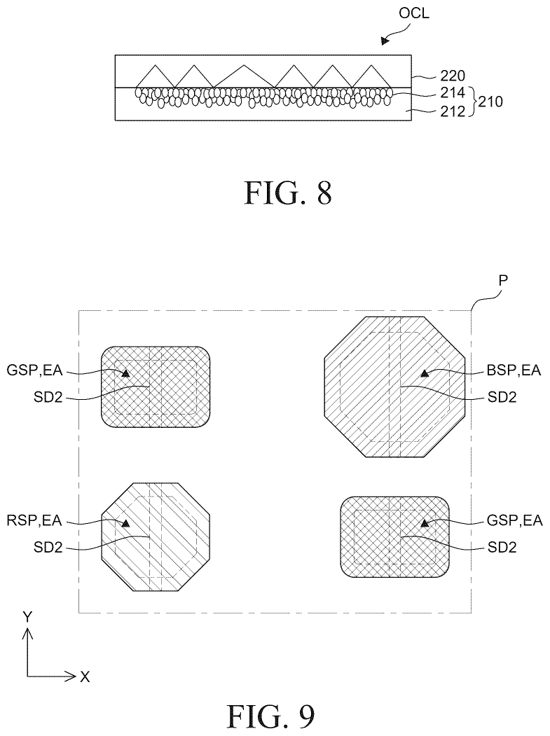

FIG. 8 is a view of an optical control layer according to one or more other embodiments of the present disclosure. Referring to FIG. 8, the light concentrating layer 220 may be formed of a plurality of prism patterns.

The above-described lenses or prism structures condense light scattered from the light scattering layer 210 to face the front. Accordingly, the amount of light extracted to the outside of the display panel 110 is increased to reduce power consumption.

Each of the plurality of lenses (or prism patterns) constituting the light concentrating layer 220 may have the same size or shape, or may be different from each other.

A width of the optical control layer OCL may be equal to or greater than a width of the opening OA1 of the black matrix BM. When the width of the optical control layer OCL is smaller than the width of the opening OA1 of the black matrix BM, there may be a problem in that the luminance decreases at a high viewing angle of 45° or more or 60° or more due to disadvantage in securing a viewing angle.

Further, a width of the optical control layer OCL may be equal to or smaller than a width of the color filter CF. When the width of the optical control layer OCL is larger than the width of the color filter CF, the effect of alleviating the rainbow mura phenomenon is insignificant, the uniformity of light is lowered, and the diffusion reflectance is increased, thereby reducing the display quality.

For example, the thickness of the optical control layer OCL may be 3 μm or less, the thickness of the light scattering layer 210 may be 1 μm or more, and the height of the lens or prism pattern constituting the light concentrating layer 220 may be 1 μm to 2 μm. In an embodiment, when the black matrix BM is formed to have a thickness of 1 μm to 2 μm and the height of the lens or prism pattern constituting the light concentrating layer 220 exceeds 2 μm, it may not be easy to form the black matrix BM disposed thereon. In addition, when the height of the lens or prism pattern constituting the light concentrating layer 220 is too low, the light concentrating effect of light may decrease. The height of the lens or prism pattern of the light concentrating layer 220 may be preferably formed to be higher than the diameter of the light scattering particles 214 in order to sufficiently secure light concentrating efficiency.

The plurality of color filters CF may be disposed on the optical control layer OCL to correspond to each of the plurality of sub pixels RSP, GSP, and BSP. Accordingly, the lower surfaces of the plurality of color filters CF may be disposed to be in direct contact with the light concentrating layer 220 of the optical control layer OCL to cover the same.

The display device according to one or more embodiments of the present disclosure is characterized in that the optical control layer OCL is disposed on the encapsulation layer ENCAP so as to correspond to each of the plurality of sub pixels. The optical control layer OCL may include a light scattering layer 210 in which a plurality of light scattering particles 214 are dispersed, and a light concentrating layer 220 disposed on the light scattering layer 210 and including a plurality of lenses. Accordingly, the reflected light formed by reflecting light incident from the outside of the display device by the anode AE is scattered by the light scattering layer 210 to improve the uniformity of the light and cancel the interference fringe, thereby preventing the occurrence of spots such as rainbow mura. Further, light scattered from the light scattering layer 210 may be condensed by the light concentrating layer 220 to be emitted to the outside of the display device. Accordingly, reflectance is lowered while maintaining high luminance, and spots such as rainbow mura are improved to provide a display device having excellent display quality. In addition, since the above effect may be achieved without using a polarizing plate, power consumption may be reduced. Therefore, even though there is a step difference in the anode AE due to the second source-drain electrode pattern SD2 disposed below the anode AE, the rainbow mura may be prevented due to distortion of the non-uniform reflected light.

Hereinafter, the effects of the present disclosure described above will be described in more detail with reference to embodiments. However, the following examples are for illustration of the present disclosure, and the scope of the present disclosure is not limited by the following examples.

### EXPERIMENTAL EXAMPLE

In one or more embodiments, as illustrated in FIG. 7, a display panel including an optical control layer patterned to correspond to an emission area of each of a plurality of sub pixels is manufactured.

As a comparative example, a display panel having the same structure as the example was manufactured except that an optical control layer was not provided.

As a reference example, a display panel having the same structure as in the embodiment was manufactured except that the optical control layer was formed on the entire display panel over the plurality of sub pixels.

FOS evaluation, diffraction analysis, and reflectance were measured for each of the display panels according to the Embodiment, Comparative Example, and Reference Example prepared as described above, respectively. The FOS evaluation indicates a state of the exterior (Front of Screen; FOS) of the display panel, and the closer the FOS evaluation result is to a strong one, the more severe the stain such as rainbow mura occurs. Diffraction analysis indicates the uniformity of light, and the lower the value, the more uniform the light. The reflectance SCI/SCE may be expressed as the sum of the positive reflectance and the diffusion reflectance SCI with respect to the diffusion reflectance SCE. The results are shown in Table 1 below.

TABLE 1

| | Comparative | Reference | |
|---|---|---|---|
| | Example | Example | Embodiment |
| optical control layer | X | ◯ (front | ◯ (pattern |
| | | structure) | structure) |
| FOS evaluation | Very strong | strong | weak |
| differentiation | 33.0 mm | 33.0 mm | 32.3 mm |
| Reflectance (SCI/SCE) | 6.32/0.61. | 5.68/0.73 | 5.75/0.69 |

Referring to Table 1, in the case of the comparative example in which the optical control layer is not provided, the stain such as the rainbow mura is very severe in the FOS evaluation, while in the case of the optical control layer, the stain is weakened compared to the comparative example. In particular, it was confirmed that the rainbow mura was the weakest when the optical control layer was not formed on the entire surface and patterned to be disposed at a position corresponding to the emission area of each of the plurality of sub pixels, which is a portion where light distortion occurs. Further, in the display device of the embodiment, it may be confirmed that the display panel of the embodiment has a lower value compared to the comparative embodiment and the reference example in the diffraction analysis. From this, it may be seen that the display panel of the embodiment has excellent light uniformity to improve the stain such as the rainbow mura.

In addition, it may be seen that the embodiment and the reference example including the optical control layer have a lower reflectance than the comparative example not including the optical control layer. Comparing the configuration and the reference example, it can be seen that when the optical control layer is patterned, the diffusion reflectance is slightly lower, but there is no significant difference.

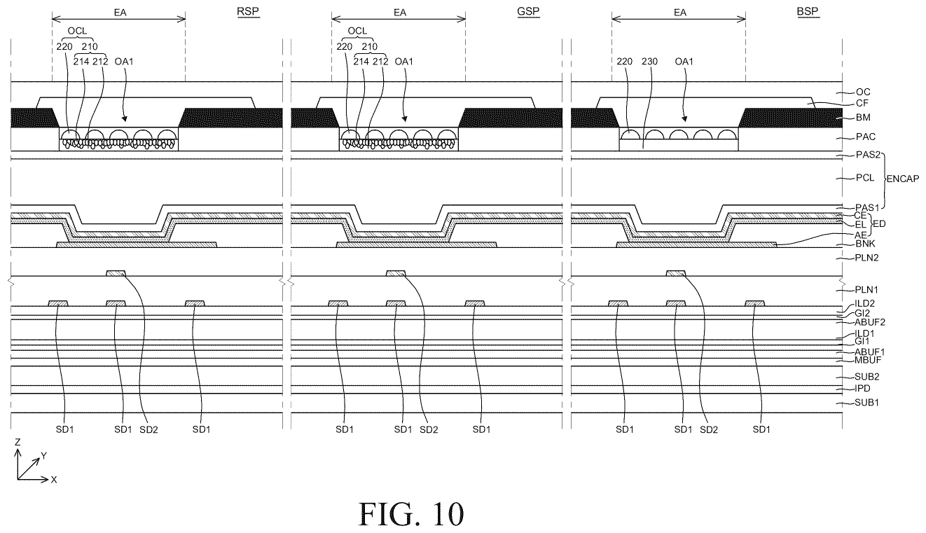

Hereinafter, a display device according to one or more other embodiments of the present disclosure will be described with reference to FIGS. 9 and 10. FIG. 9 is a plan view illustrating a placement structure of a plurality of sub pixels in a display area of a display panel according to one or more other embodiments of the present disclosure. FIG. 10 is a schematic cross-sectional view of a display device according to one or more other embodiments of the present disclosure. In the display device illustrated in FIGS. 9 and 10, the remaining components except for the size of the plurality of sub pixels and the configuration of the optical control layer are substantially the same as the display device described in FIGS. 1 to 3 and 7. Therefore, redundant descriptions of components having the same reference numerals as those of FIGS. 1 to 3, and 7 will be omitted.

For convenience of description, in FIG. 9, only an anode AE, a emission layer EL corresponding to the emission area EA, and a second source-drain electrode pattern SD2 are illustrated.

Referring to FIG. 9, one pixel P may include one blue emission area EA, one red emission area EA, and two green emission areas EA. Sub pixels SP may be disposed in the pixel P.

Specifically, one pixel P may be composed of, for example, a blue sub pixel BSP including a blue emission area EA, a red sub pixel RSP including a red emission area EA, and a green sub pixel GSP including a green emission area EA.

The sizes of the red sub pixel RSP, the green sub pixel GSP, and the blue sub pixel BSP may be formed to be different from each other in consideration of the luminance difference for each color. For example, the size of the light-emitting area EA of the blue sub pixel BSP may be larger than the size of the light-emitting area EA of the red sub pixel RSP and the size of the light-emitting area EA of the green sub pixel GSP.

Each of the emission area EA of the red sub pixel RSP, the emission area EA of the green sub pixel GSP, and the emission area EA of the blue sub pixel BSP may be disposed to overlap the second source-drain electrode pattern SD2 extending in the Y-axis direction. Accordingly, the second source-drain electrode pattern SD2 may overlap at least a part of the anode AE formed to correspond to each of the red sub pixel RSP, the green sub pixel GSP, and the blue sub pixel BSP.

That is, each of the emission area EA of the red sub pixel RSP, the emission area EA of the green sub pixel GSP, and the emission area EA of the blue sub pixel BSP may be located on the second source-drain electrode pattern SD2 extending in the Y-axis direction.

Referring to FIG. 10 together, the second source-drain electrode pattern SD2 is covered by the second planarization layer PLN2. However, the second source-drain electrode pattern SD2 may affect the flatness of the anode AE disposed above the second source-drain electrode pattern SD2. Accordingly, a partial area of the anode AE corresponding to a position at which the second source-drain electrode pattern SD2 is formed may have a step higher than that of the surroundings.

At this time, the emission area EA of the red sub pixel RSP and the emission area EA of the green sub pixel GSP having a relatively small area are greatly affected by the flatness by the second source-drain electrode pattern SD2, whereas the emission area EA of the blue sub pixel BSP is formed to have a relatively large area, so that the flatness by the second source-drain electrode pattern SD2 may not be greatly changed.

That is, the anode AE of the red sub pixel RSP and the anode AE of the green sub pixel GSP, which are formed in a narrow area under the same width condition of the second source-drain electrode pattern SD2 overlapping each of the emission area EA of the red sub pixel RSP, the emission area EA of the green sub pixel GSP, and the emission area EA of the blue sub pixel BSP, have a larger step difference due to the second source-drain electrode pattern SD2, and the anode AE of the blue sub pixel BSP is formed in a relatively large area, such that the step difference may be formed to be smaller.

Accordingly, the intensity of the reflected light formed by being reflected by the anode AE of the red sub pixel RSP and the anode AE of the green sub pixel GSP having a low flatness may be greater than the intensity of the reflected light formed by being reflected by the anode AE of the blue sub pixel BSP having a relatively high flatness.

Accordingly, the optical control layer OCL formed to correspond to each of the red sub pixel RSP, the green sub pixel GSP, and the blue sub pixel BSP may be formed differently in consideration of the difference in intensity of the reflected light.

For example, the optical control layer OCL including the light scattering layer 210 and the light concentrating layer 220 may be disposed at positions corresponding to the red sub pixel RSP and the green sub pixel GSP, respectively. The light scattering layer 210 and the light concentrating layer 220 are the same as those described in FIGS. 7 and 8, so that a redundant description will be omitted.

A transparent resin layer 230 may be disposed instead of the light scattering layer 210 at a position corresponding to the blue sub pixel BSP having a relatively weak intensity of reflected light, and the light concentrating layer 220 may be disposed on the transparent resin layer 230.

As described above, the light scattering layer 210 includes the light scattering particles 214, and the light scattering layer 210 scatters non-uniform reflected light generated due to a decrease in the flatness of the anode AE by the second source-drain electrode pattern SD2, thereby improving light uniformity. Accordingly, the light scattering layer 210 is disposed in each of the red sub pixel RSP and the green sub pixel GSP having a relatively low flatness of the anode AE to scatter reflected light to cancel interference fringes. Accordingly, it is possible to improve stains such as rainbow mura due to distortion of light.

The light scattering layer 210 may not be required for the blue sub pixel BSP having a relatively high flatness of the anode AE. Accordingly, the transparent resin layer 230 may be disposed instead of the light scattering layer 210 at a position corresponding to the blue sub pixel BSP. The transparent resin layer 230 may be formed of the same material as the light scattering layer 210 except that the transparent resin layer 230 does not include the light scattering particles 214.

Optical properties may be improved by disposing the light concentrating layer 220 that condenses light emitted from the light emitting element ED on the transparent resin layer 230. The light concentrating layer 220 is substantially the same as that described with reference to FIGS. 7 and 8, and accordingly, a redundant description will be omitted.

The display device according to one or more embodiments of the present disclosure is characterized in that the light scattering layer 210 and the light concentrating layer 220 are formed in an area corresponding to the red sub pixel RSP and the green sub pixel GSP and the transparent resin layer 230 and the light concentrating layer 220 are formed in an area corresponding to the blue sub pixel BSP in consideration of the difference in flatness of the anode AE corresponding to each sub pixel RSP, GSP, BSP. Accordingly, non-uniform reflected light generated due to low flatness of the anode AE is scattered by the light scattering layer 210 to improve the rainbow mura, and light is condensed toward the display surface in the light concentrating layer 220 to improve the display quality.

The embodiments of the present disclosure can also be described as follows:

According to one or more embodiments of the present disclosure, a display device includes a substrate including a display area in which a plurality of sub pixels is disposed, a thin film transistor disposed on the substrate and including an active layer, a gate electrode, and a first source-drain electrode pattern, a planarization layer disposed on the thin film transistor, a light emitting element disposed on the planarization layer so as to correspond to each of the plurality of sub pixels, an encapsulation layer disposed on the light emitting element, a plurality of optical control layers disposed on the encapsulation layer so as to correspond to each of the plurality of sub pixels, a plurality of color filters disposed on the optical control layer so as to partition the plurality of color filters from each other, and the optical control layer includes a light scattering layer disposed on the encapsulation layer and a light concentrating layer disposed on the light scattering layer.

According to one or more embodiments of the present disclosure, the light scattering layer may include a base resin and a plurality of light scattering particles included in the base resin.

According to one or more embodiments of the present disclosure, the light scattering particles may include one or more selected from TiO₂ particles and SiO₂ particles.

According to one or more embodiments of the present disclosure, the light scattering particles may be aggregated on the surface of the light scattering layer adjacent to the light concentrating layer.

According to one or more embodiments of the present disclosure, the light concentrating layer may include at least one of a spherical lens, a cylindrical lens, and a prism pattern.

According to one or more embodiments of the present disclosure, the black matrix may include an opening at a position corresponding to each of the plurality of sub pixels, and the width of the optical control layer may be equal to or greater than the width of the corresponding opening, equal to or smaller than the width of the color filter.

According to one or more embodiments of the present disclosure, the planarization layer may include a first planarization layer disposed on the thin film transistor and a second planarization layer disposed on the first planarization layer, and the display device may further include a second source-drain electrode pattern disposed on the first planarization layer.

According to one or more embodiments of the present disclosure, the light emitting element may include an anode disposed on the second planarization layer, an emission layer disposed on the anode, and a cathode disposed on the emission layer, and the second source-drain electrode pattern may be disposed to overlap at least a part of the anode.

According to one or more embodiments of the present disclosure, the second source-drain electrode pattern may be disposed to penetrate at least a portion of the plurality of sub pixels in the Y-axis direction.

According to one or more embodiments of the present disclosure, the anode may include a step corresponding to the second source-drain electrode pattern in the emission area of the plurality of sub pixels overlapping the second source-drain electrode pattern.

According to one or more embodiments of the present disclosure, the plurality of sub pixels may include a red sub pixel, a blue sub pixel, and a green sub pixel, and the second source-drain electrode pattern may be disposed to penetrate the emission area of each of the red sub pixel, the blue sub pixel, and the green sub pixel in the Y-axis direction.

According to one or more embodiments of the present disclosure, the optical control layer may be disposed on the encapsulation layer so as to correspond to each of the red sub pixel, the blue sub pixel, and the green sub pixel.

According to one or more embodiments of the present disclosure, the size of the emission area of the blue sub pixel is larger than the size of each of the emission area of the red sub pixel and the emission area of the green sub pixel, and the optical control layer may be disposed on the encapsulation layer so as to correspond to each of the red sub pixel and the green sub pixel.

According to one or more embodiments of the present disclosure, a transparent resin layer disposed on the encapsulation layer so as to correspond to the blue sub pixel and a light concentrating layer disposed on the transparent resin layer may be further included.

Although the embodiments of the present disclosure have been described in detail with reference to the accompanying drawings, the present disclosure is not limited thereto and may be embodied in various forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including a display area in which a plurality of sub pixels are disposed;
a thin film transistor disposed on the substrate, the thin film transistor including an active layer, a gate electrode, and a first source-drain electrode pattern;
a planarization layer disposed on the thin film transistor;
a light emitting element disposed on the planarization layer to correspond to each of the plurality of sub pixels;
an encapsulation layer disposed on the light emitting element;
a plurality of optical control layers disposed on the encapsulation layer to correspond to each of the plurality of sub pixels;
a plurality of color filters disposed on an optical control layer of the plurality of optical control layers to correspond to each of the plurality of sub pixels; and
a black matrix disposed on the encapsulation layer to partition the plurality of color filters from each other,
wherein the optical control layer includes a light scattering layer disposed on the encapsulation layer and a light concentrating layer disposed on the light scattering layer.

2. The display device according to claim 1, wherein the light scattering layer includes a base resin and a plurality of light scattering particles included in the base resin.

3. The display device according to claim 2, wherein the plurality of light scattering particles include at least one selected from TiO₂ particles and SiO₂ particles.

4. The display device according to claim 2, wherein the plurality of light scattering particles are aggregated on a surface of the light scattering layer adjacent to the light concentrating layer.

5. The display device according to claim 1, wherein the light concentrating layer includes at least one of a plurality of lenses or a plurality of prism patterns.

6. The display device according to claim 1, wherein the black matrix includes an opening at a position corresponding to each of the plurality of sub pixels,
wherein a width of the optical control layer is equal to or larger than a width of a corresponding opening, and
wherein the width of the optical control layer is equal to or smaller than a width of a color filter of the plurality of color filters.

7. The display device according to claim 1, wherein the planarization layer includes a first planarization layer disposed on the thin film transistor and a second planarization layer disposed on the first planarization layer, and
wherein the display device further includes a second source-drain electrode pattern disposed on the first planarization layer.

8. The display device according to claim 7, wherein the light emitting element includes an anode disposed on the second planarization layer, an emission layer disposed on the anode, and a cathode disposed on the emission layer, and
wherein the second source-drain electrode pattern is disposed to overlap at least a part of the anode.

9. The display device according to claim 8, wherein the second source-drain electrode pattern is disposed to penetrate an emission area of at least a part of the plurality of sub pixels in a Y-axis direction.

10. The display device according to claim 9, wherein the anode includes a step corresponding to the second source-drain electrode pattern in an emission area of the plurality of sub pixels overlapping the second source-drain electrode pattern.

11. The display device of claim 10, wherein the plurality of sub pixels include a red sub pixel, a blue sub pixel, and a green sub pixel, and
wherein the second source-drain electrode pattern is disposed to penetrate the emission area of each of the red sub pixel, the blue sub pixel, and the green sub pixel in the Y-axis direction.

12. The display device of claim 11, wherein the optical control layer is disposed on the encapsulation layer to correspond to each of the red sub pixel, the blue sub pixel, and the green sub pixel.

13. The display device of claim 11, wherein an emission area of the blue sub pixel is larger than each of an emission area of the red sub pixel and an emission area of the green sub pixel, and
wherein the optical control layer is disposed on the encapsulation layer to correspond to each of the red sub pixel and the green sub pixel.

14. The display device of claim 13, further comprising:
a transparent resin layer disposed on the encapsulation layer to correspond to the blue sub pixel; and
a light concentrating layer disposed on the transparent resin layer.
